(19) United States
(12) Patent Application Publication
(10) Pub. No.: US 2006/0292741 A1
(43) Pub. Date: Dec. 28, 2006

(54) Heat-dissipating semiconductor package and fabrication method thereof

(75) Inventors: Wen-Tsung Tseng, Taichung (TW); Ho-Yi Tsai, Taichung (TW); Chien-Ping Huang, Taichung (TW); Chih-Ming Huang, Taichung (TW); Cheng-Hsu Hsiao, Taichung (TW)

Correspondence Address: BIRCH STEWART KOLASCH & BIRCH, PO BOX 747, FALLS CHURCH, VA, 22040-0747, US

(73) Assignee: Siliconware Precision Industries Co., Ltd.

(21) Appl. No.: 11/471,516

(22) Filed: Jun. 21, 2006

(30) Foreign Application Priority Data
Jun. 22, 2005 (TW) 094120737

(51) Int. Cl. H01L 21/00

(52) U.S. Cl. 438/106

(57) ABSTRACT

A heat-dissipating semiconductor package and a fabrication method thereof are provided. A semiconductor chip is mounted and electrically connected to a substrate. A heat-dissipating structure includes a heat sink and at least one supporting portion, wherein the supporting portion is attached to the substrate at a position outside a predetermined package area for the semiconductor package, and the semiconductor chip is disposed under the heat sink. An encapsulant is formed on the substrate to encapsulate the semiconductor chip and the heat-dissipating structure, wherein a projection area of the encapsulant on the substrate is larger in size than the predetermined package area. A cutting process is performed along edges of the predetermined package area to remove parts of the encapsulant, the supporting portion and the substrate, which are located outside the predetermined package area, so as to form the semiconductor package integrated with the heat-dissipating structure.

### FIELD OF THE INVENTION

The present invention relates to heat-dissipating semiconductor packages and fabrication methods thereof, and more particularly, to a semiconductor package integrated with a heat-dissipating structure and a method for fabricating the semiconductor package.

### BACKGROUND OF THE INVENTION

Ball Grid Array (BGA) semiconductor package capable of providing sufficient input/output (I/O) connections has been widely adopted for incorporating a semiconductor chip formed with high-density arranged electronic elements and electronic circuits. Such highly integrated chip produces a large amount of heat during operation, and if the heat is not efficiently dissipated from the chip, the heat accumulates and adversely affects electrical performance of the chip and reliability of the semiconductor package. Moreover, in order to protect internal circuits of the package against external moisture and contaminant, an encapsulant is typically provided to encapsulate the chip. However, the encapsulant is usually made of a resin material having poor thermal conductivity (a coefficient of thermal conduction thereof is 0.8 w/m° K.), such that the heat generated by an active surface of the chip where many circuits are disposed is difficult to be effectively transmitted via the encapsulant and dissipated out of the package, thereby resulting in heat accumulation that degrades the performance and lifetime of the chip.

In light of the above problem of unsatisfactory heat dissipation, there has been proposed mounting a heat-dissipating structure in the BGA semiconductor package, The related prior arts include U.S. Pat. Nos. 5,877,552; 5,736,785; 5,977,626; 5,851,337; 6,552,428; 6,246,115; 6,429,512; 6,400,014; and 6,462,405.

FIG. 1 shows a heat-dissipating semiconductor package 1 with a heat-dissipating structure 13 as disclosed by U.S. Pat. No. 5,977,626. The heat-dissipating structure 13 of the semiconductor package 1 comprises a flat portion 130 having a top surface exposed from an encapsulant 14; a plurality of supporting portions 131 for supporting the flat portion 130 to be positioned above a semiconductor chip 11; and a plurality of contact portions 132 extended from the supporting portions 131 and having a plurality of protruded portions 137 attached to a substrate 10. The supporting portions 131 are peripherally mounted to the flat portion 130 and are extended downwardly and outwardly to the contact portions 132 to thereby form a cavity 18 for accommodating a plurality of active/passive components (such as chips, bonding wires, capacitors, etc.). The above arrangement allows heat generated by the chip 11 during operation to be dissipated via the heat-dissipating structure 13 to the atmosphere.

As for the development of Chip Scale Package (CSP), a substrate is becoming sized similar to a chip, which requires relatively more elements to be incorporated on the substrate with a limited area. However, the foregoing heat-dissipating structure 13 with the protruded portions 137 necessitates reserving a certain area on the contact portions 132 for accommodating the protruded portions 137, such that the contact portions 132 occupy a relatively large area on the substrate and thus undesirably limit the layout of I/O connections (e.g. fingers) and passive components on the substrate.

Further, as the contact portions 132 take up a peripheral region of the substrate, all active/passive components can only be disposed within the cavity 18 formed by the supporting portions 131 and the flat portion 130 of the heat-dissipating structure 13. This arrangement usually makes the substrate not capable of accommodating sufficient active/passive components thereon to provide the semiconductor package with desirable performance and functionality, such that the heat-dissipating structure 13 is not considered suitable for a highly integrated semiconductor package e.g. CSP. Accordingly, as shown in FIG. 2, U.S. Pat. No. 6,720,649 discloses an improved heat-dissipating structure 23 for expanding a circuit layout area on a substrate 20. The heat-dissipating structure 23 includes a plurality of supporting portions 232 disposed at four corners thereof, wherein a space is formed between every two adjacent supporting portions 232 and allows conductive elements (such as bonding wires 22 for electrically connecting a chip 21 to the substrate 20) to pass through the space. The supporting portions 232 are only disposed at the corners of the heat-dissipating structure 23 and thus occupy a relatively smaller area on the substrate 20, such that more electronic components 27 and bonding wires 22 can be accommodated on the substrate 20.

Even if the above heat-dissipating structure 23 has the supporting portions 232 only disposed at the corners thereof, it is understood that the area on the substrate 20, which is predetermined to mount the supporting portions 232, cannot be used for accommodating the electronic components 27 and bonding wires 22, thereby not maximizing or optimizing the circuit layout area on the substrate 20.

Moreover, the aforementioned heat-dissipating structures are all attached to the substrate by an adhesive. Due to mismatch in coefficient of thermal expansion (CTE) between the heat-dissipating structure and the substrate, delamination is prone to occur at the attachment positions between the heat-dissipating structure and the substrate during a thermal cycle, thereby adversely affecting the reliability of packaged products. If a strengthened adhesive is used to affix the heat-dissipating structure to the substrate, the heat-dissipating structure when being subjected to thermal stresses may cause a solder mask layer on the substrate to be delaminated from the substrate and even cause damage to circuits underneath the solder mask layer, such that the packaged products are damaged as a result.

Besides, when the substrate mounted with the heat-dissipating structure is placed in a mold cavity to undergo a molding process for forming an encapsulant, a top surface of the heat-dissipating structure needs to abut against a top wall of the mold cavity to ensure no gap formed therebetween, otherwise a molding resin used for forming the encapsulant would flash to the top surface of the heat-dissipating structure. To prevent resin flashes, U.S. Pat. No. 6,522,428 discloses the use of a heat-dissipating structure, after being attached to the substrate, having a height slight larger than a depth of the mold cavity by about 0.1 mm, so as to allow the top wall of the mold cavity to effectively press on the heat-dissipating structure to avoid resin flashes. However, the drawback of such arrangement is that, if the pressure from the top wall of the mold cavity to the heat-dissipating structure is over large, it may lead to cracks of substrate circuits disposed underneath the supporting portions of the heat-dissipating structure.

Therefore, the problem to be solved is to provide a heat-dissipating semiconductor package, which can overcome the foregoing drawbacks such as the heat-dissipating structure occupying the substrate area, delamination between the heat-dissipating structure and the substrate, delamination of the solder mask layer on the substrate, and circuit cracks.

### SUMMARY OF THE INVENTION

In light of the above drawbacks in the prior art, an objective of the present invention is to provide a heat-dissipating semiconductor package and a fabrication method thereof, so as to prevent a heat-dissipating structure in the semiconductor package from occupying area on a substrate.

Another objective of the present invention is to provide a heat-dissipating semiconductor package and a fabrication method thereof, so as to allow electronic components to be mounted on a substrate in the semiconductor package without interference.

Still another objective of the present invention is to provide a heat-dissipating semiconductor package and a fabrication method thereof, so as to avoid delamination between a heat-dissipating structure and a substrate in the semiconductor package.

A further objective of the present invention is to provide a heat-dissipating semiconductor package and a fabrication method thereof, so as to avoid delamination of a solder mask layer of a substrate and circuit cracks due to thermal stresses with a heat-dissipating structure being mounted on the substrate in the semiconductor package.

A further objective of the present invention is to provide a heat-dissipating semiconductor package and a fabrication method thereof, so as to prevent damage to circuits of a substrate due to pressure from a mold exerted to a heat-dissipating structure mounted on the substrate during a molding process.

To achieve the above and other objectives, the present invention proposes a fabrication method of a heat-dissipating semiconductor package, comprising the steps of: mounting and electrically connecting at least one semiconductor chip to at least one substrate; providing a heat-dissipating structure comprising a heat sink and supporting portions extended downwardly from the heat sink, and attaching the supporting portions of the heat-dissipating structure to the substrate, wherein the semiconductor chip is disposed under the heat sink, and the supporting portions are attached to positions on the substrate outside a predetermined package area for the semiconductor package; forming an encapsulant on the substrate to encapsulate the semiconductor chip and the heat-dissipating structure, wherein a projection area of the encapsulant on the substrate is larger in size than the predetermined package area; and performing cutting along edges of the predetermined package area to remove parts of the encapsulant, the supporting portions of the heat-dissipating structure and the substrate, which are located outside the predetermined package area. The semiconductor chip can be electrically connected to the substrate by a flip-chip or wire-bonding technique. A top surface of the heat sink can be exposed from the encapsulant. The at least one substrate can comprise a single substrate, or linearly arranged substrates. In the latter case, after completing a molding process for forming the encapsulant, a plurality of solder balls can be implanted on the substrate and a subsequent singulation process can be carried out.

In another embodiment, the fabrication method of a heat-dissipating semiconductor package according to the present invention comprises the steps of: mounting and electrically connecting at least one semiconductor chip to at least one substrate, and positioning the substrate in an opening of a carrier, wherein a surface area of the substrate is close in size to a predetermined package area for the semiconductor package; providing a heat-dissipating structure comprising a heat sink and supporting portions extended downwardly from the heat sink, and attaching the supporting portions of the heat-dissipating structure to the carrier, wherein the semiconductor chip is disposed under the heat sink; performing a molding process to form an encapsulant on the substrate and the carrier to encapsulate the semiconductor chip and the heat-dissipating structure, wherein a projection area of the encapsulant on the substrate and the carrier is larger in size than a projection area of the heat-dissipating structure; and performing cutting along edges of the predetermined package area to remove parts of the encapsulant and the supporting portions of the heat-dissipating structure, which are located outside the predetermined package area. A top surface of the heat sink can be exposed from the encapsulant. A plurality of solder balls can be implanted on a surface of the substrate where the semiconductor chip is not mounted.

According to the foregoing fabrication method, the present invention also proposes a heat-dissipating semiconductor package comprising: at least one substrate having a first surface and an opposed second surface; at least one semiconductor chip mounted on and electrically connected to the first surface of the substrate; an encapsulant formed on the first surface of the substrate, for encapsulating the semiconductor chip, wherein sides of the encapsulant are flush with sides of the substrate; and a heat-dissipating structure encapsulated in the encapsulant, the heat-dissipating structure comprising a heat sink and supporting portions extended downwardly from periphery of the heat sink, wherein the heat sink is disposed above the semiconductor chip and has a top surface exposed from the encapsulant, and at least a part of the supporting portions is removed when the semiconductor package is formed. The top surface of the heat sink of the heat-dissipating structure can be fully or partially exposed from the encapsulant, and the supporting portions of the heat-dissipating structure can be fully or partially removed.

Therefore, by the heat-dissipating semiconductor package and the fabrication method thereof of the present invention, a heat-dissipating structure with supporting portions is mounted on a substrate having a semiconductor chip mounted thereon, wherein the supporting portions of the heat-dissipating structure are attached to positions on the substrate outside a predetermined package area for the semiconductor package and thus do not occupy a circuit layout area on the substrate for accommodating electronic components such as the semiconductor chip and passive components, thereby providing the maximum circuit layout area on the substrate. Then, the substrate incorporated with the semiconductor chip and the heat-dissipating structure is placed in a mold having a mold cavity to perform a molding process, wherein a projection area of the mold cavity on the substrate is larger in size than the predetermined package area. The mold can be used to clamp and press on the heat-dissipating structure in a manner that positions on the substrate subjected to the pressure from the mold are located outside the circuit layout area, thereby avoiding circuits of the substrate being damaged by the pressure from the mold. During the molding process, a resin material is filled in the mold cavity to form an encapsulant for encapsulating the semiconductor chip, and a projection area of the encapsulant on the substrate is larger in size than the predetermined package area. After that, a cutting process is performed to remove parts of the encapsulant, the supporting portions of the heat-dissipating structure and the substrate, which are located outside the predetermined package area.

Further, in another embodiment of the present invention, a semiconductor chip is mounted on and electrically connected to a substrate having a surface area dimensionally close to a predetermined package area, and then the substrate is positioned in an opening of a carrier. Supporting portions of a heat-dissipating structure are attached to the carrier, such that the supporting portions do not occupy a circuit layout area on the substrate for accommodating electronic components.

As the supporting portions of the heat-dissipating structure in the semiconductor package of the present invention are not directly disposed on the circuit layout area of the substrate, the substrate can incorporate a sufficient number of the semiconductor chip and other electronic components, thereby enhancing the electrical performance of the semiconductor package. Thus, the problem of damaging substrate circuits due to pressure applied from the mold to the supporting portions of the heat-dissipating structure during the molding process can be solved in the present invention. Moreover, the heat-dissipating structure may further be formed with a protruded portion, a roughened portion or a groove, which face toward the semiconductor chip, or a dummy die can further be mounted on the semiconductor chip, so as to enhance the heat dissipating efficiency of the semiconductor package.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross-sectional view of a heat-dissipating semiconductor package disclosed by U.S. Pat. No. 5,977,626;

FIG. 2 (PRIOR ART) is a top view of a heat-dissipating semiconductor package disclosed by U.S. Pat. No. 6,720,649;

FIGS. 3A to 3D are cross-sectional views showing steps of a fabrication method of a heat-dissipating semiconductor package in accordance with a first preferred embodiment of the present invention;

FIG. 4A is a top view showing an encapsulant formed on a substrate to encapsulate a semiconductor chip in the fabrication method of FIGS. 3A to 3D;

FIG. 4B is a top view showing a heat sink of a heat-dissipating structure being formed with indented portions corresponding to edges of a predetermined package area;

FIG. 4C is a top view showing a top surface of the heat sink being partially exposed from the encapsulant;

FIG. 4D is a cross-sectional view showing the semiconductor package of FIG. 4C taken along line 4D-4D;

FIG. 4E is a cross-sectional view showing a part of supporting portions of the heat-dissipating structure remaining in the encapsulant after a cutting process when a projection area of the heat sink of the heat-dissipating structure on the substrate is smaller in size than the predetermined package area;

FIGS. 5A to 5E are cross-sectional views showing steps of a fabrication method of a heat-dissipating semiconductor package in accordance with a second preferred embodiment of the present invention;

FIG. 6 is a cross-sectional view of a heat-dissipating semiconductor package in accordance with a third preferred embodiment of the present invention;

FIG. 7 is a cross-sectional view of a heat-dissipating semiconductor package in accordance with a fourth preferred embodiment of the present invention;

FIG. 8 is a cross-sectional view of a heat-dissipating semiconductor package in accordance with a fifth preferred embodiment of the present invention; and

FIG. 9 is a cross-sectional view of a heat-dissipating semiconductor package in accordance with a sixth preferred embodiment of the present invention.

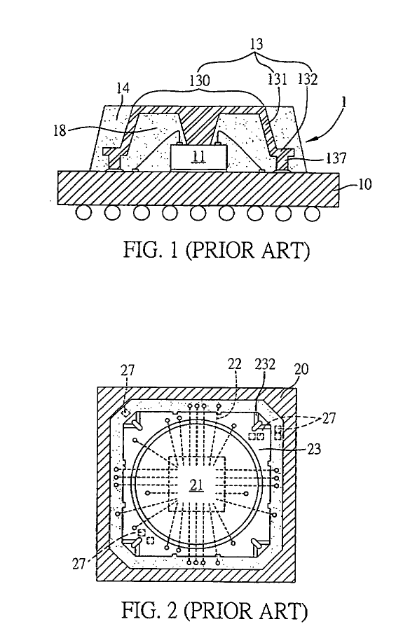

### DETAILED DESCRIPTION OF THE PREFERRED EMBODIMENTS

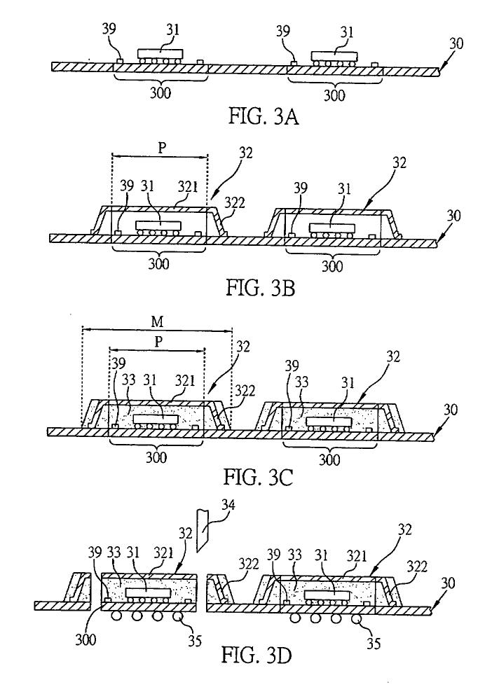

Preferred embodiments of a heat-dissipating semiconductor package and a fabrication method thereof as proposed in the present invention are described as follows with reference to FIGS. 3 to 9. It should be noted that the drawings are simplified schematic diagrams only showing relevant components for the present invention, and the arrangement or layout of components can be more complicated in practical implementation.

### First Preferred Embodiment

FIGS. 3A to 3D illustrate steps of a fabrication method of a heat-dissipating semiconductor package according to a first preferred embodiment of the present invention.

As shown in FIG. 3A, a substrate module plate 30 is provided, which comprises a plurality of substrates 300 that can be arranged in a linearly arranged. Next, at least one semiconductor chip 31 is mounted on and electrically connected to each of the substrates 300, wherein the semiconductor chip 31 can be electrically connected to the substrate 300 by a flip-chip technique (as shown in the drawing) or a wire-bonding technique. At least one passive component 39 may further be disposed on and electrically connected to the substrate 300. Alternatively, the fabrication method of the present invention can be implemented using a single substrate to undergo subsequent packaging processes.

Then, as shown in FIG. 3B, a heat-dissipating structure 32 is provided, which includes a heat sink 321 and a plurality of supporting portions 322 extended downwardly from periphery of the heat sink 321. The heat-dissipating structure 32 is mounted on each of the substrates 300 by attaching the supporting portions 322 to positions on the substrate 300 outside a predetermined package area P for the semiconductor package to be fabricated, that is, the supporting portions 322 are attached to the substrate 300 at positions outside a circuit layout area of the substrate 300. The semiconductor chip 31 and the passive component 39 on the substrate 300 are disposed under the heat sink 321 of the heat-dissipating structure 32. This arrangement prevents the heat-dissipating structure 32 from occupying the circuit layout area on the substrate 300 that is reserved for accommodating electronic components such as the semiconductor chip 31 and the passive component 39, thereby providing a maximum circuit layout area on the substrate 300.

Then, as shown in FIG. 3C, a molding process is performed, which allows each of the substrates 300, with the semiconductor chip 31 and the heat-dissipating structure 32 being mounted thereon, to be placed and clamped between an upper mold and a lower mold of an encapsulation mold (not shown), wherein the upper mold has a mold cavity for an encapsulating resin to be injected thereinto and a top surface of the heat sink 321 abuts against a top wall of the mold cavity, such that the encapsulating resin injected into the mold cavity can fill the mold cavity to form an encapsulant 33 that encapsulates the semiconductor chip 31, the passive component 39 and the heat-dissipating structure 32, with the top surface of the heat sink 321 being exposed from the encapsulant 33. A projection area M of the encapsulant 33 (i.e. a projection area of the mold cavity) on the substrate 300 is larger in size than the predetermined package area P and a projection area of the heat-dissipating structure 32 on the substrate 300, such that positions on the substrate 300 corresponding to the supporting portions 322 of the heat-dissipating structure 32 suffering clamping pressure from the encapsulation mold are located outside the circuit layout area, thereby preventing the pressure from the encapsulation mold from damaging circuits of the substrate 300 during the molding process.

Then, as shown in FIG. 3D, a cutting process is performed using a cutting tool 34 (such as a saw) to cut along edges of the predetermined package area P and remove parts of the encapsulant 33, the supporting portions 322 of the heat-dissipating structure 32 and the substrate 300, which are located outside the predetermined package area P. Further, before or after the cutting process, a plurality of solder balls 35 can be implanted on a surface of the substrate 300 opposite to the surface where the semiconductor chip 31 is mounted.

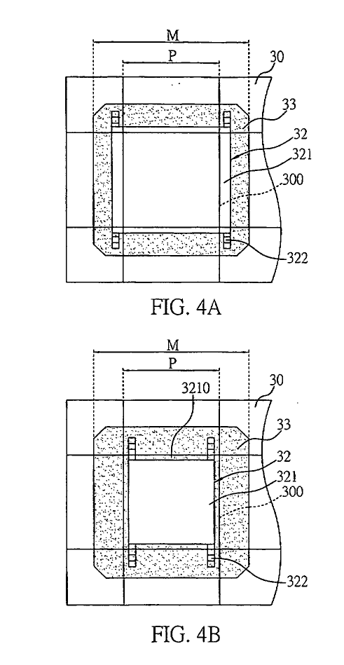

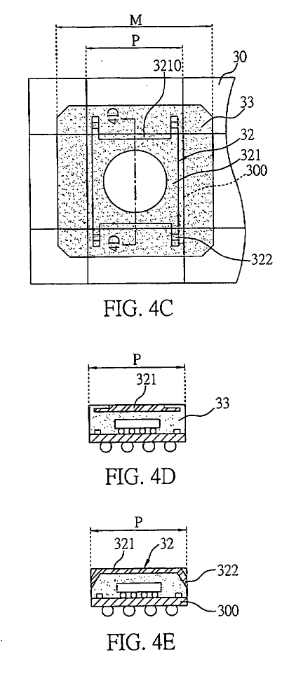

FIG. 4A is a top view showing the encapsulant 33 formed on the substrate 300 of the substrate module plate 30 to encapsulate the semiconductor chip 31 in the fabrication method of FIGS. 3A to 3D, wherein the projection area M of the encapsulant 33 is larger in size than the predetermined package area P. Referring to FIG. 4B, at least one edge of the heat sink 321 of the heat-dissipating structure 32 can be formed with an indented portion 3210 corresponding to at least one of the edges of the predetermined package area P so as to reduce wear of the cutting tool in the subsequent cutting process. The provision of the indented portion 3210 is optional depending on the fabrication conditions. Alternatively, as shown in FIG. 4C and FIG. 4D taken along line 4D-4D of FIG. 4C, the top surface of the heat sink 321 is partially exposed from the encapsulant 33 and is partially encapsulated in the encapsulant 33 to enhance the bonding strength between the heat sink 321 and the encapsulant 33.

Referring further to FIG. 4E, when a projection area of the heat sink 321 of the heat-dissipating structure 32 on the substrate 300 is smaller in size than the predetermined package area P, during the cutting process, the supporting portions 322 of the heat-dissipating structure 32 would be partially cut off and partially remain in the encapsulant 33. On the other hand, if the projection area of the heat sink 321 of the heat-dissipating structure 32 on the substrate 300 is dimensionally larger than the predetermined package area P, the supporting portions 322 of the heat-dissipating structure 32 would be completely removed in the cutting process.

According to the foregoing fabrication method, the present invention also provides a heat-dissipating semiconductor package comprising: a substrate 300 having a first surface and an opposed second surface; at least one semiconductor chip 31 mounted on and electrically connected to the first surface of the substrate 300; an encapsulant 33 formed on the first surface of the substrate 300, for encapsulating the semiconductor chip 31, wherein sides of the encapsulant 33 are flush with sides of the substrate 300; and a heat-dissipating structure 32 encapsulated in the encapsulant 33, the heat-dissipating structure 32 comprising a heat sink 321 and at least one supporting portion 322 extended downwardly from periphery of the heat sink 321, wherein the heat sink 321 is disposed above the semiconductor chip 31 and has a top surface exposed from the encapsulant 33, and the supporting portion 322 is at least partially removed when the semiconductor package is formed. The top surface of the heat sink 321 of the heat-dissipating structure 32 can be completely or partially exposed from the encapsulant 33, and at least one edge of the heat sink 321 can be formed with an indented portion 3210. Further, the supporting portion 322 of the heat-dissipating structure 32 can be completely or partially removed. Moreover, a passive component 39 can further be disposed on the first surface of the substrate 300, and a plurality of solder balls 35 can be implanted to the second surface of the substrate 300.

### Second Preferred Embodiment

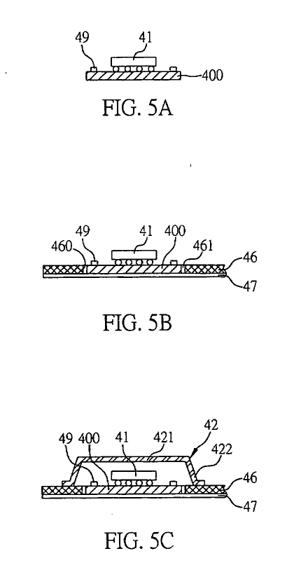

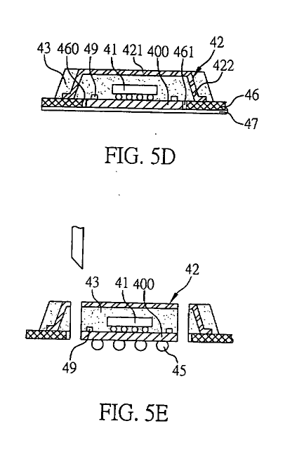

FIGS. 5A to 5E illustrate steps of a fabrication method of a heat-dissipating semiconductor package according to a second preferred embodiment of the present invention.

As shown in FIG. 5A, a substrate 400 is provided, which has a surface area dimensionally close to a predetermined package area for the semiconductor package to be fabricated. Next, at least one semiconductor chip 41 and at least one passive component 49 are mounted on and electrically connected to the substrate 400. The semiconductor chip 41 can be electrically connected to the substrate 400 by a flip-chip technique (as shown in the drawing) or a wire-bonding technique.

Then, as shown in FIG. 5B, a carrier 46 having an opening 460 is provided to allow the substrate 400 mounted with the semiconductor chip 41 and the passive component 49 thereon to be positioned in the opening 460 of the carrier 46, wherein the opening 460 has a size sufficient to accommodate the substrate 400 such that the substrate 400 is embedded in the opening 460. A tape 47 may be attached to lower surfaces of the substrate 400 and carrier 46, for sealing a gap 461 between the opening 460 and the substrate 400 and securely positioning the substrate 400. The tape 47 can be made of a thermal resistant polymer material. The carrier 46 can be made of an organic insulating material such as FR4, FR5, and BT (bismaleimide triazine), and the number of the opening 460 of the carrier 46 can be one or more for accommodating one or more substrates integrated with chips thereon. Alternatively, a plurality of small tapes may be employed to seal the gap between the substrate 400 and the carrier 46 to reduce the amount of tape material being used, and the small tapes can be removed after the molding process. Further, the gap between the substrate 400 and the carrier 46 may alternatively be filled with a polymer filling material such as solder mask or epoxy resin by a dispensing technique, which also secures the substrate 400 in place.

Then, as shown in FIG. 5C, a heat-dissipating structure 42 is provided, which comprises a heat sink 421 and a plurality of supporting portions 422 extended downwardly from periphery of the heat sink 421. The supporting portions 422 of the heat-dissipating structure 42 are attached to the carrier 46 but not the substrate 400, and the semiconductor chip 41 and the passive component 49 are disposed under the heat sink 421, such that the heat-dissipating structure 42 does not occupy a circuit layout area of the substrate 400 for accommodating electronic components such as the semiconductor chip 41 and the passive component 49, thereby providing a maximum circuit layout area on the substrate 400.

Then, as shown in FIG. 5D, a molding process is performed to form an encapsulant 43 on the substrate 400 and the carrier 46 to encapsulate the semiconductor chip 41, the passive component 49 and the heat-dissipating structure 42, with a top surface of the heat sink 421 being exposed from the encapsulant 43. A projection area of the encapsulant 43 on the substrate 400 and the carrier 46 is larger in size than a projection area of the heat-dissipating structure 42, and the encapsulant 43 can be filled into the gap 461 between the substrate 400 and the opening 460 of the carrier 46.

Then, as shown in FIG. 5E, the tape 47 is removed from the substrate 400 and the carrier 46. A plurality of solder balls 45 are implanted to a surface of the substrate 400 where the semiconductor chip 41 is not mounted, namely the lower surface of the substrate 400, such that the semiconductor chip 41 can be electrically connected to an external device via the solder balls 45. A cutting process is performed to remove parts of the encapsulant 43 and the supporting portions 422 of the heat-dissipating structure 42, which are located outside the predetermined package area.

### Third Preferred Embodiment

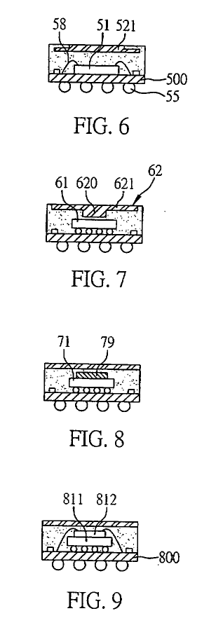

FIG. 6 is a cross-sectional view of a heat-dissipating semiconductor package according to a third preferred embodiment of the present invention, wherein the heat-dissipating semiconductor package in this embodiment can be obtained by employing either one of the foregoing fabrication methods, and the heat sink 521 in the semiconductor package is formed with at least one indented portion and has a partially exposed top surface. As shown in FIG. 6, the third embodiment differs from the foregoing embodiments in that, the semiconductor chip 51 is electrically connected to the substrate 500 via a plurality of bonding wires 58 by a wire-bonding process and is further electrically connected to an external device via a plurality of solder balls 55 implanted to the substrate 500.

### Fourth Preferred Embodiment

FIG. 7 is a cross-sectional view of a heat-dissipating semiconductor package according to a fourth preferred embodiment of the present invention, wherein this heat-dissipating semiconductor package is structurally similar to those illustrated in the foregoing embodiments, and the heat sink 621 of the heat-dissipating structure 62 in the semiconductor package is formed with at least one indented portion and has an exposed top surface. As shown in FIG. 7, the fourth embodiment differs from the foregoing embodiments in that, the heat-dissipating structure 62 is further formed with a protruded portion 620 facing toward the semiconductor chip 61 to enhance the heat dissipating efficiency of the semiconductor package. Further, the heat-dissipating structure 62 may selectively be formed with a roughened portion or a groove facing toward the semiconductor chip 61 to similarly enhance the heat dissipating efficiency.

### Fifth Preferred Embodiment

FIG. 8 is a cross-sectional view of a heat-dissipating semiconductor package according to a fifth preferred embodiment of the present invention. As shown in FIG. 8, the heat-dissipating semiconductor package of the fifth embodiment is structurally similar to those illustrated in the foregoing embodiments, but differs from them in that a dummy die 79 is further provided on the semiconductor chip 71 to enhance the heat dissipating efficiency of the semiconductor package.

### Sixth Preferred Embodiment

FIG. 9 is a cross-sectional view of a heat-dissipating semiconductor package according to a sixth preferred embodiment of the present invention. As shown in FIG. 9, the heat-dissipating semiconductor package of the sixth embodiment is structurally similar to those illustrated in the foregoing embodiments, but differs from them in that a plurality of chips 811, 812 are stacked on the substrate 800 to enhance the electrical performance of the semiconductor package.

It should be noted that the semiconductor package structures described in the foregoing embodiments can be flexibly selected and combined according to practical design requirements.

Therefore, by the heat-dissipating semiconductor package and the fabrication method thereof of the present invention, a heat-dissipating structure with supporting portions is mounted on a substrate having a semiconductor chip mounted thereon, wherein the supporting portions of the heat-dissipating structure are attached to positions on the substrate outside a predetermined package area for the semiconductor package and thus do not occupy a circuit layout area on the substrate for accommodating electronic components such as the semiconductor chip and passive components, thereby providing the maximum circuit layout area on the substrate. Then, the substrate incorporated with the semiconductor chip and the heat-dissipating structure is placed in a mold having a mold cavity to perform a molding process, wherein a projection area of the mold cavity on the substrate is larger in size than the predetermined package area. The mold can be used to clamp and press on the heat-dissipating structure in a manner that positions on the substrate subjected to the pressure from the mold are located outside the circuit layout area, thereby avoiding circuits of the substrate being damaged by the pressure from the mold. During the molding process, a resin material is filled in the mold cavity to form an encapsulant for encapsulating the semiconductor chip, and a projection are of the encapsulant on the substrate is larger in size than the predetermined package area. After that, a cutting process is performed to remove parts of the encapsulant, the supporting portions of the heat-dissipating structure and the substrate, which are located outside the predetermined package area.

Further, the present invention also allows a semiconductor chip to be mounted on and electrically connected to a substrate having a surface area dimensionally close to a predetermined package area, and then allows the substrate to be positioned in an opening of a carrier. Supporting portions of a heat-dissipating structure are attached to the carrier, such that the supporting portions do not occupy a circuit layout area on the substrate for accommodating electronic components.

As the supporting portions of the heat-dissipating structure in the semiconductor package of the present invention are not directly disposed on the circuit layout area of the substrate, the substrate can incorporate a sufficient number of the semiconductor chip and other electronic components, thereby enhancing the electrical performance of the semiconductor package. Thus, the problem of damaging substrate circuits due to pressure applied from the mold to the supporting portions of the heat-dissipating structure during the molding process can be solved in the present invention. Moreover, the heat-dissipating structure may further be formed with a protruded portion, a roughened portion or a groove, which face toward the semiconductor chip, or a dummy die can further be mounted on the semiconductor chip, so as to enhance the heat dissipating efficiency of the semiconductor package.

The present invention has been described using exemplary preferred embodiments above, however, it is to be understood that the scope of the present invention is not limited to the disclosed embodiments. On the contrary, it is intended to cover various modifications and similar changes. The scope of the claims, therefore, should be accorded the broadest interpretation so as to encompass all such modifications and similar arrangements.

What is claimed is:

1. A fabrication method of a heat-dissipating semiconductor package, comprising the steps of:
mounting and electrically connecting at least one semiconductor chip to at least one substrate;
providing a heat-dissipating structure comprising a heat sink and at least one supporting portion extended from the heat sink, and mounting the supporting portion of the heat-dissipating structure to the substrate, wherein the semiconductor chip is disposed under the heat sink, and the supporting portion is attached to a position on the substrate outside a predetermined package area for the semiconductor package;
forming an encapsulant on the substrate to encapsulate the semiconductor chip and the heat-dissipating structure, wherein a projection area of the encapsulant on the substrate is larger in size than the predetermined package area; and
performing a cutting process along edges of the predetermined package area to remove parts of the encapsulant, the supporting portion of the heat-dissipating structure and the substrate, which are located outside the predetermined package area.

2. The fabrication method of claim 1, wherein the at least one substrate comprises one of a single substrate, an array of substrates, and linearly arranged substrates.

3. The fabrication method of claim 1, wherein the semiconductor chip is electrically connected to the substrate by one of a flip-chip technique and a wire-bonding technique.

4. The fabrication method of claim 1, wherein a top surface of the heat sink is at least partly exposed from the encapsulant.

5. The fabrication method of claim 1, wherein the supporting portion of the heat-dissipating structure is at least partly removed.

6. The fabrication method of claim 1, wherein the heat-dissipating structure is formed with at least one of a protruded portion, a roughened portion and a groove, which face toward the semiconductor chip.

7. The fabrication method of claim 1, wherein the at least one semiconductor chip comprises a plurality of semiconductor chips stacked on the substrate.

8. The fabrication method of claim 1, wherein the semiconductor chip is further provided with a dummy die thereon.

9. The fabrication method of claim 1, further comprising mounting and electrically connecting at least one passive component to the substrate.

10. The fabrication method of claim 1, wherein the heat sink is formed with an indented portion corresponding to at least one of the edges of the predetermined package area.

11. A fabrication method of a heat-dissipating semiconductor package, comprising the steps of:
mounting and electrically connecting at least one semiconductor chip to at least one substrate, and positioning the substrate in an opening of a carrier, wherein a surface area of the substrate is dimensionally close to a predetermined package area for the semiconductor package;
providing a heat-dissipating structure comprising a heat sink and at least one supporting portion extended from the heat sink, and mounting the supporting portion of the heat-dissipating structure to the carrier, wherein the semiconductor chip is disposed under the heat sink;
performing a molding process to form an encapsulant on the substrate and the carrier to encapsulate the semiconductor chip and the heat-dissipating structure, wherein a projection area of the encapsulant on the substrate and the carrier is larger in size than a projection area of the heat-dissipating structure; and
performing a cutting process along edges of the predetermined package area to remove parts of the encapsulant and the supporting portion of the beat-dissipating structure, which are located outside the predetermined package area.

12. The fabrication method of claim 11, wherein the substrate is positioned in the opening of the carrier by one of filling a filling material in a gap between the substrate and the opening of the carrier and attaching at least one tape to the substrate and the carrier to seal the gap, wherein the tape is removable after the molding process.

13. The fabrication method of claim 11, wherein the carrier is made of an organic insulating material selected from the group consisting of FR4, FR5 and BT.

14. The fabrication method of claim 11, wherein the at least one substrate comprises one of a single substrate, and linearly arranged substrates.

15. The fabrication method of claim 11, wherein the semiconductor chip is electrically connected to the substrate by one of a flip-chip technique and a wire-bonding technique.

16. The fabrication method of claim 11, wherein a top surface of the heat sink is at least partly exposed from the encapsulant.

17. The fabrication method of claim 11, wherein the supporting portion of the heat-dissipating structure is at least partly removed.

18. The fabrication method of claim 11, wherein the heat-dissipating structure is formed with at least one of a protruded portion, a roughened portion and a groove, which face toward the semiconductor chip.

19. The fabrication method of claim 11, wherein the at least one semiconductor chip comprises a plurality of semiconductor chips stacked on the substrate.

20. The fabrication method of claim 11, wherein the semiconductor chip is further provided with a dummy die thereon.

21. The fabrication method of claim 11, further comprising mounting and electrically connecting at least one passive component to the substrate.

22. The fabrication method of claim 11, wherein the heat sink is formed with an indented portion corresponding to at least one of the edges of the predetermined package area.

23. A heat-dissipating semiconductor package comprising:
a substrate having a first surface and an opposed second surface;
at least one semiconductor chip mounted on and electrically connected to the first surface of the substrate;
an encapsulant formed on the first surface of the substrate, for encapsulating the semiconductor chip, wherein sides of the encapsulant are flush with sides of the substrate; and
a heat-dissipating structure encapsulated in the encapsulant, the heat-dissipating structure comprising a heat sink and at least one supporting portion extended from the heat sink, wherein the heat sink is disposed above the semiconductor chip and has a top surface exposed from the encapsulant, and the supporting portion is at least partially removed when the semiconductor package is formed.

24. The heat-dissipating semiconductor package of claim 23, wherein the semiconductor chip is electrically connected to the substrate by one of flip-chip type connection and wire-bonding type connection.

25. The heat-dissipating semiconductor package of claim 23, wherein the heat-dissipating structure is formed with at least one of a protruded portion, a roughened portion and a groove, which face toward the semiconductor chip.

26. The heat-dissipating semiconductor package of claim 23, wherein the at least one semiconductor chip comprises a plurality of semiconductor chips stacked on the substrate.

27. The heat-dissipating semiconductor package of claim 23, wherein the semiconductor chip is further provided with a dummy die thereon.

28. The heat-dissipating semiconductor package of claim 23, wherein the top surface of the heat sink is at least partly exposed from the encapsulant.

29. The heat-dissipating semiconductor package of claim 23, wherein the supporting portion of the heat-dissipating structure is completely removed.

30. The heat-dissipating semiconductor package of claim 23, further comprising at least one passive component mounted on and electrically connected to the first surface of the substrate.

31. The heat-dissipating semiconductor package of claim 23, wherein the heat sink is formed with an indented portion along at least one edge thereof.

32. A heat-dissipating semiconductor package comprising:
a substrate having a first surface and an opposed second surface;
at least one semiconductor chip mounted on and electrically connected to the first surface of the substrate;
an encapsulant formed on the first surface of the substrate, for encapsulating the semiconductor chip, wherein sides of the encapsulant are flush with sides of the substrate; and
a heat-dissipating structure encapsulated in the encapsulant, the heat-dissipating structure comprising a heat sink and at least one supporting portion extended from the heat sink, wherein the heat sink is disposed above the semiconductor chip, with a top surface of the heat sink being exposed from the encapsulant and at least one edge of the heat sink being formed with an indented portion, and the supporting portion is at least partially removed when the semiconductor package is formed.

33. The heat-dissipating semiconductor package of claim 32, further comprising at least one passive component mounted on and electrically connected to the first surface of the substrate.

34. The heat-dissipating semiconductor package of claim 32, wherein the top surface of the heat sink is at least partially exposed from the encapsulant.

35. The heat-dissipating semiconductor package of claim 23, wherein the supporting portion of the heat-dissipating structure is completely removed.
